(19) United States
(12) Patent Application Publication
(10) Pub. No.: US 2013/0299209 A1
(43) Pub. Date: Nov. 14, 2013

(54) ELECTRONIC DEVICE WITH A DUSTPROOF SHIELD

(71) Applicants: HONG FU JIN PRECISION INDUSTRY (SHENZHEN) CO., LT, Shenzhen (CN); HON HAI PRECISION INDUSTRY CO., LTD., New Taipei (TW)

(72) Inventor: JI-FENG QIU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/686,991

(22) Filed: Nov. 28, 2012

(30) Foreign Application Priority Data
May 11, 2012 (CN) 201220211077.X

(51) Int. Cl. H05K 5/00

(52) U.S. Cl. CPC H05K 5/0095
USPC 174/50.54

(57) ABSTRACT

An electronic device includes a housing, an electronic component mounted to the housing, and a first dustproof component. The electronic component includes a first part received in the housing. The first dustproof component is secured to the housing and is provided around the first part, for closing the first part.

### BACKGROUND

1. Technical Field

The present disclosure relates to electronic devices, and more particularly to an electronic device having a dustproof shield.

2. Description of Related Art

Disc players for reading/writing to optical discs such as compact discs, digital video discs and mini discs include a housing and electronic components received in the housing. However, gaps between a cover and a body of the electronic device are susceptible to dust seeping into the housing of the electronic device. Thus, the electronic components tend to be contaminated by dust and may malfunction or become damaged.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an embodiment of an electronic device.

FIG. 2 is a partial, exploded view of the electronic device of FIG. 1.

### DETAILED DESCRIPTION

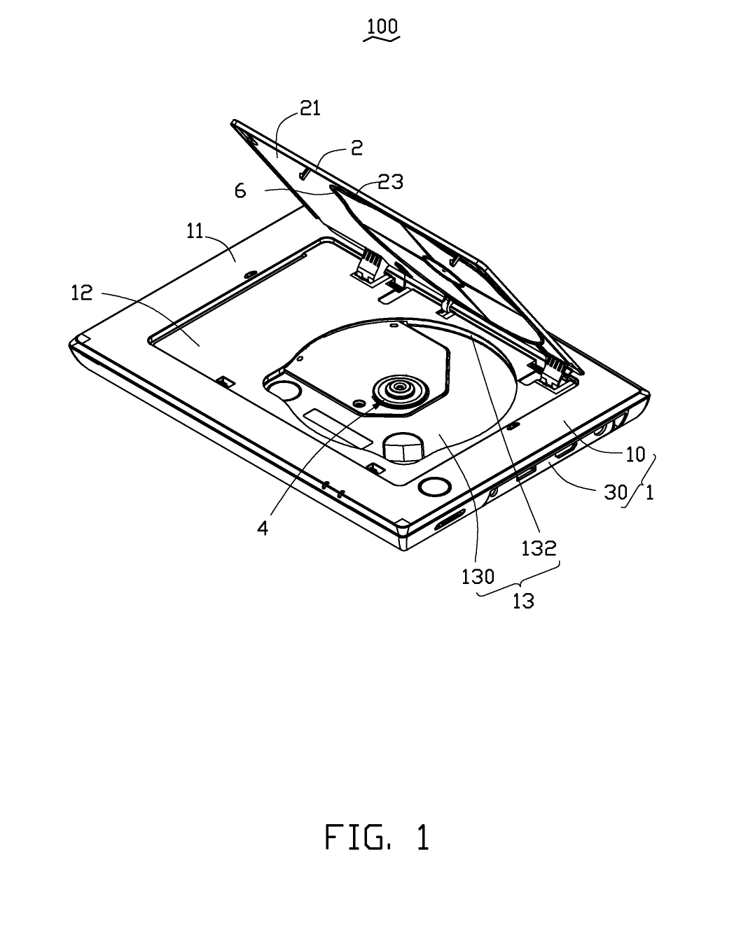

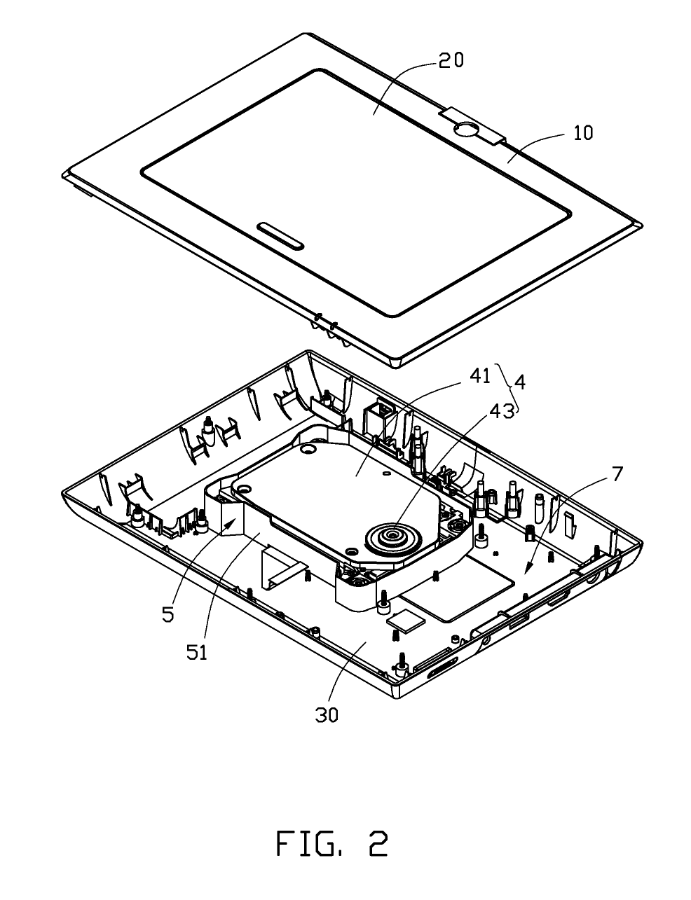

Referring to FIGS. 1 and 2, an electronic device 100 includes a housing 1, a cover 2, an electronic component 4, and a dustproof shield designed for protecting the electronic device 100 from dust. The electronic device 100 may be a notebook computer, a disc player, or other electronic devices. In the embodiment, the electronic device 100 is a disc player.

The housing 1 in the embodiment is substantially rectangular, and includes an upper case 10 and a lower case 30 opposite to the upper case 10. The upper case 10 cooperates with the lower case 30 to define a receiving space 7 for receiving the components and circuitry of the electronic device 100. A surface of the upper case 10 opposite to the lower case 30 is recessed to define a rectangle receiving portion 12 for receiving the cover 10. A bottom of the receiving portion 12 is further recessed to define a substantially circular recess 13 for receiving an optical disc (not shown). The recess 13 includes a bottom portion 130 and a sidewall 132 protruded from the rim of the bottom portion 130.

The cover 2 is rotatably connected to the housing 1 and is capable of being opened and closed relative to the housing 1. The cover 2 includes an outer surface 20 and an inner surface 21 opposite to the outer surface 20. A protruding portion 23 protrudes from the inner surface 21, with a shape corresponding to the shape of the recess 13. When the cover 2 covers on the housing 1, the cover 2 is received in the receiving portion 12. The protruding portion 23 is received in the recess 13 and contacts with the inner surface of the sidewall 132.

The electronic component 4 is set in the housing 1 with a section protruding out of the bottom portion 130 of the recess 13. The electronic component 4 is divided into a first part 41 and a second part 43. The first part 41 is received in the receiving space 7. The second part 43 is exposed out of the bottom portion of the recess 13. In the embodiment, the electronic component 4 is a traverse module.

The dustproof configuration includes a first dustproof component 5 and a second dustproof component 6. The first dustproof component 5 is substantially rectangular, and protrudes from a surface of the lower case 30 facing the upper case 10. The first dustproof component 5 includes a plurality of protecting pieces 51. The protecting pieces 51 serially interconnect with each other and are arranged around the first part 41 of the electronic component 4. The height of each protecting piece 51 relative to the bottom of the lower case 30 is higher than the height of the electronic component 4 relative to the bottom of the lower case 30. In other embodiment, the first dustproof component 5 also can be formed by a plurality of protecting pieces 51 cooperating with one of the sidewalls of the lower case 30. The first dustproof component 5 can be integrally formed with the lower case 30.

The second dustproof component 6 is secured to the inner surface 21 and encircles the protruding portion 23. In the embodiment, the second dustproof component 6 is a rubber dust-proof washer adhering to the protruding portion 23.

In use, when the upper case 10 is secured to the lower case 30, an end of the first dustproof component 5 opposite to the lower case 30 contacts with the upper case 10. Thus, the upper case 10, the first dustproof component 5 and the lower case 30 cooperatively define a first closed space (not shown) for preventing the first part 41 of the electronic component 4 from being penetrated by dust. When the cover 2 is received in the recess 13, the second dustproof component 6 tightly contacts with the inner surface of the sidewall 132. The cover 2, the second dustproof component 6 and the recess 13 cooperatively define a second closed space (not shown) for preventing the second part 43 of the electronic component 4 from being penetrated by dust. Thus, the entire electronic component 4 is sealed by the cover 2, the second dustproof component 6, the recess 13, the first dustproof component 5 and the lower case 30, to be protected from dust.

Although information and the advantages of the present embodiments have been set forth in the foregoing description, together with details of the structures and functions of the present embodiments, the disclosure is illustrative only; changes may be made in detail, especially in the matters of shape, size, and arrangement of parts within the principles of the present embodiments to the full extent indicated by the broad general meaning of the terms in which the appended claims are expressed.

What is claimed is:

1. An electronic device, comprising:
a housing;
an electronic component mounted to the housing, the electronic component comprising a first part received in the housing; and
a first dustproof component secured to the housing and arranged around the first part;
wherein the first dustproof component cooperates with the housing to seal the first part to protect the electronic component from penetration by dust.

2. The electronic device as claimed in claim 1, wherein the housing comprises a lower case and an upper case secured to the lower case, the first dustproof protrudes from the lower case for cooperating with the upper and lower cases to seal the first part.

3. The electronic device as claimed in claim 2, wherein the height of the first dustproof component relative to the bottom of the lower case is higher than the height of the electronic component; when the upper case closes on the lower case, an end of the first dustproof component opposite to the lower case contacts with the upper case.

4. The electronic device as claimed in claim 3, wherein the first dustproof component is integrally formed with the lower case.

5. The electronic device as claimed in claim 1, wherein the electronic device further comprises a cover and a second dustproof component secured to the cover, the cover is capable of being opened and closed to the housing; the electronic component comprises a second part exposed out of the housing; when the cover closes on the housing, the second dustproof component closes the second part for protecting the electronic component from penetration by dust.

6. The electronic device as claimed in claim 5, wherein the housing defines a recess, the a second part is exposed out of the bottom of the receiving portion, the cover comprises a protruding portion corresponding to the receiving portion; when the cover closes on the housing, the protruding portion is received in the recess for closing the second part.

7. The electronic device as claimed in claim 6, wherein the second dustproof component is a rubber dust-proof washer encircles the protruding portion; when the cover closes to the housing, the second dustproof is received in the recess for closing the second part.
